(19) United States
(12) Patent Application Publication
(10) Pub. No.: US 2025/0183068 A1
(43) Pub. Date: Jun. 5, 2025

(54) SUBSTRATE COOLING APPARATUS USING CONDUCTION AND RADIANCE

(71) Applicant: ASM IP Holding B.V., Almere (NL)

(72) Inventors: Mandar Vijay Deshpande, Phoenix, AZ (US); Samer Banna, Phoenix, AZ (US); Mitsunao Shibasaki, Ebina (JP)

(21) Appl. No.: 18/961,225

(22) Filed: Nov. 26, 2024

Related U.S. Application Data
(60) Provisional application No. 63/604,575, filed on Nov. 30, 2023.

(51) Int. Cl. H01L 21/67

(52) U.S. Cl. CPC H01L 21/67201; H01L 21/67103

(57) ABSTRACT

An apparatus for cooling substrates is presented. The apparatus comprising: a chamber housing; a first port disposed in the first wall configured to be sealable from a first environment; a second port disposed in the second wall configured to be sealable from a second environment; a first support disposed between the top and the bottom of the chamber housing; a second support disposed between the first support and the bottom of the chamber housing; a first body disposed just below the top wall; and a second body disposed just above the bottom wall, wherein an emissivity of the first body and an emissivity of the second body are equal to or greater than a predetermined threshold.

### CROSS-REFERENCE TO RELATED APPLICATION(S)

This application claims the benefit of U.S. Provisional Application 63/604,575 filed on Nov. 30, 2023, the entire contents of which are incorporated herein by reference.

### FIELD OF INVENTION

The present disclosure relates to a substrate cooling chamber, more particularly to a load lock chamber in a substrate processing system configured to cool down the temperature of the processed substrate efficiently and effectively.

### BACKGROUND OF THE DISCLOSURE

In wafer processing, the wafers need cooling in various steps. Typically, the wafers are cooled in the vacuum load lock chamber before exposed to the atmosphere.

Currently, a cooling plate is used for cooling where the wafer is placed for cooling. Although this method is effective, it is not very scalable if multiple wafers are needed to be cooled simultaneously.

Therefore, an efficient way to cool down more than one wafers is needed.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, an apparatus for cooling substrates, the apparatus is further configured to transfer a substrate between a first environment with a first pressure and a second environment with a second pressure, the apparatus comprising: a chamber housing having a first wall, a second wall opposite to the first wall, a third wall, a fourth wall opposite to the third wall, a top wall and a bottom wall defining a chamber volume therebetween; a first port disposed in the first wall configured to be sealable from the first environment; a second port disposed in the second wall configured to be sealable from the second environment; a first support disposed between the top wall and the bottom wall; a second support disposed between the first support and the bottom wall; a first body disposed just below the top wall; and a second body disposed just above the bottom wall, wherein the first body and the second body can absorb a heat emitted from a first substrate placed on the first support and a second substrate placed on the second support respectively, and an emissivity of the first body and an emissivity of the second body are equal to or greater than a predetermined threshold.

In at least one aspect, the first environment is an equipment front end module (EFEM) for providing substrates into the apparatus, and the second environment is a processing module where substrates are processed, and the first pressure and the second pressure are different.

In at least one aspect, each of the first support and the second support comprising a curved inner portion and a lip, and the lip is configured to be extending radially inwards from the inner portion.

In at least one aspect, each of the first support and the second support comprising a curved inner portion and a lip, and the lip comprises a plurality of pins.

In at least one aspect, a shape of each of the plurality of pins is one of cylinder, cone-tipped cylinder, triangular prism, and square prism.

In at least one aspect, a length of the lip is equal to or greater than a predetermined length.

In at least one aspect, the apparatus further comprising a first rail and a second rail, wherein the first support and the second support are disposed on the first rail and the second rail and configured to be movable up and down.

In at least one aspect, the first rail and the second rail are directly attached to the third wall and fourth wall.

In at least one aspect, the first support and the second support are positioned at first upper position and first lower position respectively when receiving substrates and the first support and the second support are configured to move to second upper position and second lower position respectively when cooling the substrates.

In at least one aspect, a first distance between the first body and the second upper position and a second distance between the second body and the second lower position are equal to or less than a predetermined distance.

In at least one aspect, the apparatus further comprising a controller electrically coupled to the first support and the second support and configured to control an upward and downward movement of the first support and the second support.

In accordance with one embodiment there may be provided, a substrate processing assembly, the assembly comprising: an equipment front end module including an equipment front end module chamber having one or more interface openings and a robot arm for moving substrates; a plurality of processing chambers configured to process substrates; and a load lock chamber configured to cool substrates and to transfer substrates between the equipment front end module and the plurality of processing chambers, the load lock chamber comprising: a chamber housing having a first wall, a second wall opposite to the first wall, a third wall, a fourth wall opposite to the third wall, a top wall and a bottom wall defining a chamber volume therebetween; a first port disposed in the first wall configured to be sealable from a first environment; a second port disposed in the second wall configured to be sealable from a second environment; a first support disposed between the top wall and the bottom wall; a second support disposed between the first support and the bottom wall; a first body disposed just below the top wall; and a second body disposed just above the bottom wall, wherein an emissivity of the first body and an emissivity of the second body are equal to or greater than a predetermined threshold.

In at least one aspect, each of the first support and the second support comprising a curved inner portion and a lip, and the lip is configured to be extending radially inwards from the inner portion.

In at least one aspect, each of the first support and the second support comprising a curved inner portion and a lip, and the lip comprises a plurality of pins.

In at least one aspect, a shape of each of the plurality of pins is one of cylinder, cone-tipped cylinder, triangular prism, and square prism.

In at least one aspect, a length of the lip is equal to or greater than a predetermined length.

In at least one aspect, the load lock chamber further comprising: a first rail and a second rail, wherein the first support and the second support are disposed on the first rail and the second rail and configured to be movable up and down.

In at least one aspect, the first support and the second support are positioned at first upper position and first lower position respectively when receiving substrates; and the first support and the second support are configured to move to second upper position and second lower position respectively when cooling the substrates.

In at least one aspect, a first distance between the first body and the second upper position and a second distance between the second body and the second lower position are equal to or less than a predetermined distance.

In at least one aspect, the assembly further comprising: a controller electrically coupled to the first support and the second support and configured to control an upward and downward movement of the first support and the second support.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a schematic overview of the overall system according to an embodiment of the present disclosure.

FIG. 2 illustrates a perspective view of the substrate cooling apparatus (mode 1) according to an embodiment of the present disclosure.

FIG. 3 illustrates a perspective view of the substrate cooling apparatus (mode 2) according to another embodiment of the present disclosure.

FIG. 4 illustrates a front view of the substrate cooling apparatus according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

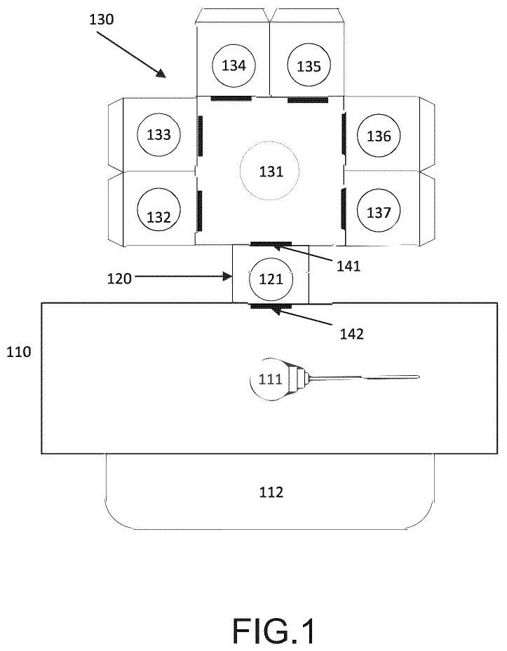

FIG. 1 illustrates a schematic overview of the overall system according to an embodiment of the present disclosure.

The chamber 120 is positioned in between an equipment front end module 110 and a wafer processing module 130. Substrates are provided into the equipment front end module 110 from the substrate carrier 112 and the robot arm 111 in the equipment front end module 110 moves the substrates. The substrates may be processed in the reaction chambers 132˜137 and moved by a robot 131.

The chamber 120 may be called as load lock chamber 120 and it may have two ports. A first port 141 may be disposed in a first wall which is between the load lock chamber 120 and the wafer processing module 130. A second port 142 may be disposed in a second wall opposite to the first wall and the second wall is between the load lock chamber 120 and the equipment front end module 110. The first and second ports 141, 142 may seal the load lock chamber 120 when closed. Substrates may be transferred between the equipment front end module 110 and the load lock chamber 120 via the second port 142 and between the load lock chamber 120 and the wafer processing module 130 via the first port 141.

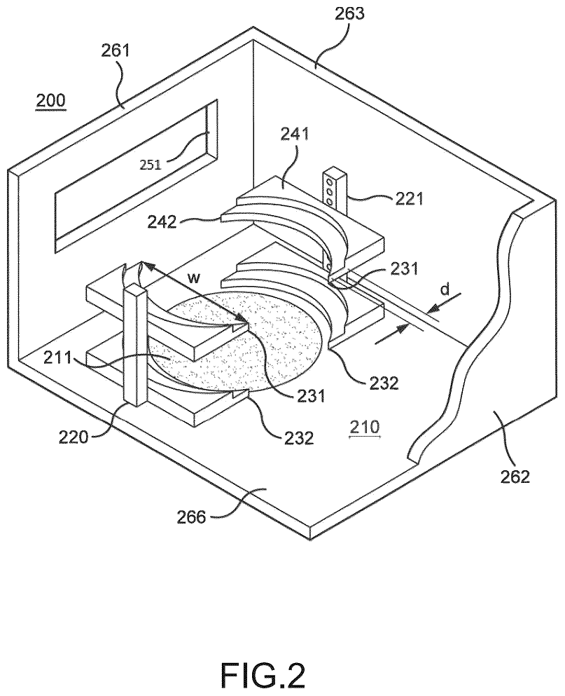

FIG. 2 illustrates a mode of a perspective view of the substrate cooling apparatus according to an embodiment of the present disclosure.

The load lock chamber 200 has a first wall 261, a second wall 262 opposite to the first wall 261, a third wall 263, a fourth wall (not drawn) opposite to the third wall 263, a bottom wall 266 and a top wall (not drawn). The walls define chamber housing 210.

A first port 251 may be disposed in the first wall 261 and although it is not drawn, it is evident that a second port may be disposed in the second wall 262.

In the chamber housing 210, a first support 231 and a second support 232 may be arranged in that order from the top wall down and substrates may be placed on each of the supports 231, 232 for cooling.

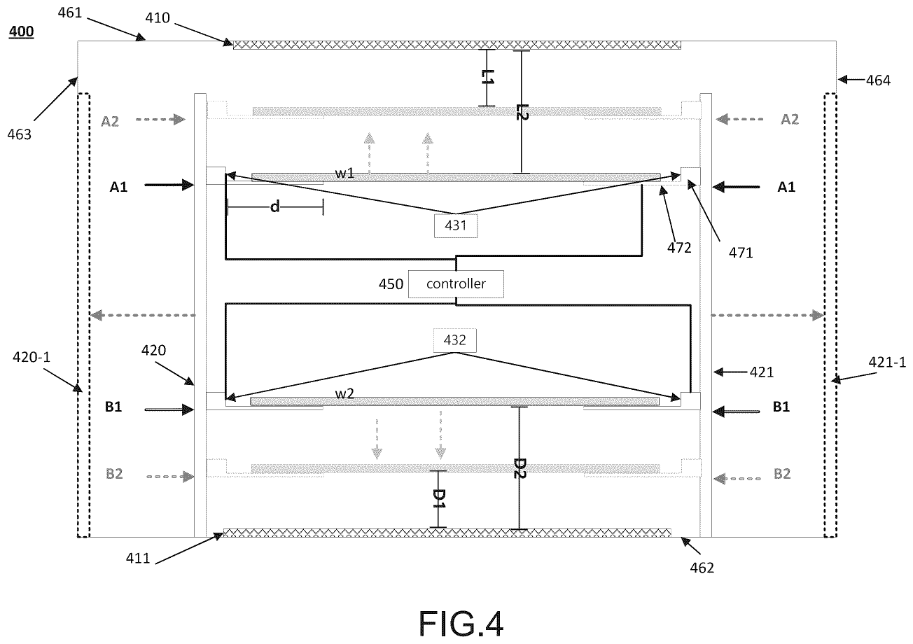

For cooling the substrates, a first body may be placed just below the top wall and a second body 211 may be placed just above the bottom wall 266. (The first body and top wall will be shown and explained in FIG. 4)

An emissivity of the first body (e1) and an emissivity of the second body (e2) may be equal to or greater than a predetermined threshold. Because a high emissivity of a material comes together with a high absorptance, a matter with high emissivity may absorb more heat than a matter with lower emissivity. Therefore, the predetermined threshold may need to be a value close to 1.0 and preferably the threshold would be 0.9. Such a configuration may allow multiple wafers to be cooled simultaneously.

Each of the first and second support 231, 232 may comprise an inner portion 241 and a lip 242. The inner portion 241 may be curved to hold a round substrate more easily. The lip 242 may be extended radially inward from the inner portion. The more area a substrate (with high temperature) contacts the lip, the faster the substrate cools down by conductance. The length of the lip (d) may be needed to be equal to or greater than a predetermined length for better conductance cooling.

The advantages afforded by large contact areas in terms of throughput improvement due to cooling where contact area may be relatively large outweigh risk of particle generation, such as when the temperature differential is relatively small and sliding of the wafer across the support relatively small due to little deformation of the wafer during cooling.

A first rail 220 and a second rail 221 may be disposed in the chamber housing 210 to support the first support 231 and second support 232. The first and second rails 220, 221 may be installed independently as shown.

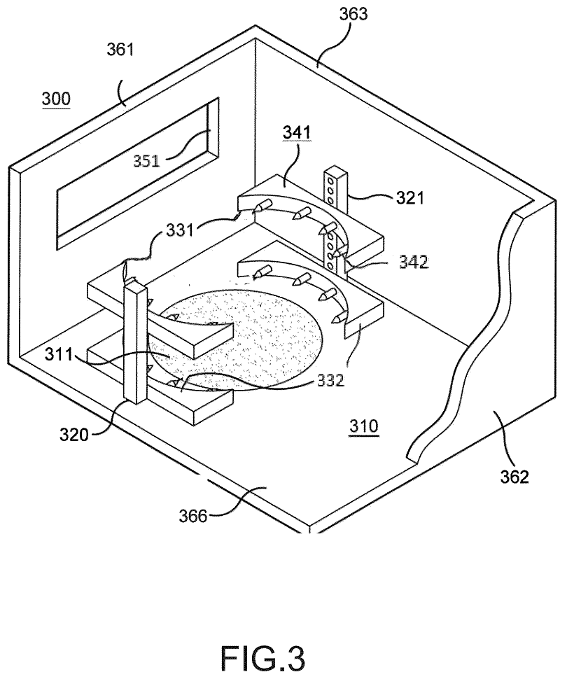

FIG. 3 illustrates another mode of a perspective view of the substrate cooling apparatus according to an embodiment of the present disclosure.

The load lock chamber 300 has a first wall 361, a second wall 362 opposite to the first wall 361, a third wall 363, a fourth wall (not drawn) opposite to the third wall 363, a bottom wall 366 and a top wall (not drawn). The walls define chamber housing 310.

A first port 351 may be disposed in the first wall 361 and although it is not drawn, it is evident that a second port may be disposed in the second wall 362.

In the chamber housing 310, a first support 331 and a second support 332 may be arranged in that order from the top wall down and substrates may be placed on each of the supports 331, 232 for cooling.

For cooling the substrates, a first body may be placed just below the top wall and a second body 311 may be placed just above the bottom wall 366.

Each of the first and second support 331, 332 may comprise an inner portion 341 and a lip. The inner portion 341 may be curved to hold a round substrate more easily. The lip may be extended radially inward from the inner portion and may comprise a plurality of pins 342 and the shape of the pins could be one of cylinder, cone-tipped cylinder, a triangular prism, and a square prism.

The relatively small contact area by the pin-like lip in FIG. 3 can be advantageous in applications where the temperature differential is relatively high and particle issue can be reduced as the wafer slides across a relatively small surface area while cooling.

A first rail 320 and a second rail 321 may be disposed in the chamber housing 310 to support the first support 331 and second support 332. The first and second rails 320, 321 may be installed independently as shown.

Since there's no cooling stage or a cooling station, tool footprint does not increase. Particles are not increased by additional parts touching the wafer during cooling stage. The number of wafer transfers which typically degrades tool's throughput is not increased by this method. Impact on the manufacturing cost and maintenance-ability is further minimized by such a method as the number of moving parts are minimal.

FIG. 4 illustrates a front view of the substrate cooling apparatus according to an embodiment of the present disclosure. In FIG. 4, the first and second wall cannot be drawn, but the third and fourth walls 463, 464 and the top wall 461 and the bottom wall 462 may be shown.

The first rail 420 and the second rail 421 may be erected from the bottom wall 462 and the first support 431 and the second support 432 may be disposed on the first and second rail 420, 421. The first and second supports 431, 432 may be configured to be movable up and down, sliding up and down on the first and second rail 420, 421. The first rail 420 and the second rail 421 may be installed on the third wall 463 and on the fourth wall 464 (420-1, 421-1).

The first support 431 may be placed at position A1 when receiving a substrate (w1) but for efficient cooling using radiance, the first support 431 may move upward at position A2 to place the substrate w1 to a position nearer to the first body 410. The distance (L1) from the first body 410 to the position A2 would be equal to or less than a predetermined distance. In the present disclosure, the predetermined distance would be preferably 5 mm.

The second support 432 may be placed at position B1 when receiving a substrate (w2) but for efficient cooling using radiance, the second support 432 may move downward at position B2 to place the substrate w2 to a position nearer to the second body 411. The distance (D1) from the second body 411 to the position B2 would be equal to or less than a predetermined distance. In the present disclosure, the predetermined distance would be preferably 5 mm.

The first support 431 may comprise an inner portion 471 and a lip 472. The lip 472 may be used for cooling the substrates by conductance.

The first and second rails 420, 421 and the walls of the chamber housing (461˜464 & first and second walls) may also need to be made of the high conductance material for maximizing the cooling effect by conductance.

If the first and second rails 420-1, 421-1 are attached to the third and fourth walls 463, 464, a heat from the substrate may be conducted more and the substrate would be cooled down more efficiently.

For efficient and effective cooling effect, a controller 450 may be electrically coupled to the first support 431 and the second support 432. The controller 450 may be configured to move up the first support 431 when a substrate w1 may be placed on the first support 431 and move down the second support 432 when a substrate w2 may be placed on the second support 432.

In all, the wafer cooling apparatus according to an embodiment of the present disclosure may use radiance and conductance to efficiently cool down the temperature of substrates.

The above-described arrangement of system is merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. An apparatus for cooling substrates, the apparatus is further configured to transfer a substrate between a first environment with a first pressure and a second environment with a second pressure, the apparatus comprising:
a chamber housing having a first wall, a second wall opposite to the first wall, a third wall, a fourth wall opposite to the third wall, a top wall and a bottom wall defining a chamber volume therebetween;
a first port disposed in the first wall configured to be sealable from the first environment;
a second port disposed in the second wall configured to be sealable from the second environment;
a first support disposed between the top wall and the bottom wall;
a second support disposed between the first support and the bottom wall;
a first body disposed just below the top wall; and
a second body disposed just above the bottom wall,
wherein the first body and the second body can absorb a heat emitted from a first substrate placed on the first support and a second substrate placed on the second support respectively, and
an emissivity of the first body and an emissivity of the second body are equal to or greater than a predetermined threshold.

2. The apparatus according to the claim 1, wherein the first environment is an equipment front end module (EFEM) for providing the substrates into the apparatus, and
wherein the second environment is a processing module where the substrates are processed, and
wherein the first pressure and the second pressure are different.

3. The apparatus according to claim 1, wherein each of the first support and the second support comprising a curved inner portion and a lip, and
wherein the lip is configured to be extending radially inwards from the inner portion.

4. The apparatus according to claim 1, wherein each of the first support and the second support comprising a curved inner portion and a lip, and
wherein the lip comprises a plurality of pins.

5. The apparatus according to claim 4, wherein a shape of each of the plurality of pins is one of cylinder, cone-tipped cylinder, triangular prism, and square prism.

6. The apparatus according to claim 3, wherein a length of the lip is equal to or greater than a predetermined length.

7. The apparatus according to claim 3, further comprising:
a first rail and a second rail, wherein the first support and the second support are disposed on the first rail and the second rail and configured to be movable up and down.

8. The apparatus according to the claim 7, wherein the first rail and the second rail are directly attached to the third wall and the fourth wall.

9. The apparatus according to the claim 7, wherein the first support and the second support are positioned at a first upper position and a first lower position respectively when receiving the substrates; and
wherein the first support and the second support are configured to move to a second upper position and a second lower position respectively when cooling the substrates.

10. The apparatus according to the claim 9, wherein a first distance between the first body and the second upper position and a second distance between the second body and the second lower position are equal to or less than a predetermined distance.

11. The apparatus according to the claim 7, further comprising:
a controller electrically coupled to the first support and the second support and configured to control an upward and downward movement of the first support and the second support.

12. A substrate processing assembly, the assembly comprising:
an equipment front end module including an equipment front end module chamber having one or more interface openings and a robot arm for moving substrates;
a plurality of processing chambers configured to process the substrates; and
a load lock chamber configured to cool the substrates and to transfer the substrates between the equipment front end module and the plurality of processing chambers, the load lock chamber comprising:
a chamber housing having a first wall, a second wall opposite to the first wall, a third wall, a fourth wall opposite to the third wall, a top wall and a bottom wall defining a chamber volume therebetween;
a first port disposed in the first wall configured to be sealable from a first environment;
a second port disposed in the second wall configured to be sealable from a second environment;
a first support disposed between the top wall and the bottom wall;
a second support disposed between the first support and the bottom wall;
a first body disposed just below the top wall; and
a second body disposed just above the bottom wall, wherein an emissivity of the first body and an emissivity of the second body are equal to or greater than a predetermined threshold.

13. The assembly according to claim 12, wherein each of the first support and the second support comprising a curved inner portion and a lip, and the lip is configured to be extending radially inwards from the inner portion.

14. The assembly according to claim 12, wherein each of the first support and the second support comprising a curved inner portion and a lip, and the lip comprises a plurality of pins.

15. The assembly according to claim 14, wherein a shape of each of the plurality of pins is one of cylinder, cone-tipped cylinder, triangular prism, and square prism.

16. The assembly according to claim 13, wherein a length of the lip is equal to or greater than a predetermined length.

17. The assembly according to claim 13, the load lock chamber further comprising:
a first rail and a second rail, wherein the first support and the second support are disposed on the first rail and the second rail and configured to be movable up and down.

18. The assembly according to the claim 17, wherein the first support and the second support are positioned at a first upper position and a first lower position respectively when receiving the substrates; and
wherein the first support and the second support are configured to move to a second upper position and a second lower position respectively when cooling the substrates.

19. The assembly according to the claim 18, wherein a first distance between the first body and the second upper position and a second distance between the second body and the second lower position are equal to or less than a predetermined distance.

20. The assembly according to the claim 17, further comprising:
a controller electrically coupled to the first support and the second support and configured to control an upward and downward movement of the first support and the second support.
